(19) United States
(12) Patent Application Publication
(10) Pub. No.: US 2006/0111243 A1
(43) Pub. Date: May 25, 2006

(54) Methods and apparatuses for fabricating thin film transistors

(75) Inventors: Feng-Yuan Gan, Hsinchu City (TW); Han-Tu Lin, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/143,155

(22) Filed: Jun. 2, 2005

(30) Foreign Application Priority Data
Nov. 22, 2004 (TW) 93135851

(51) Int. Cl. H01L 39/14

(52) U.S. Cl. 505/193

(57) ABSTRACT

Methods and apparatuses for fabricating thin film transistors. An apparatus comprises a first chamber and a second chamber. A substrate comprising a metal gate formed thereon is brought into the first chamber to form a passivation layer on the metal gate. The substrate is then transported to the second chamber to form a gate insulating layer and a semiconductor layer on the passivation layer. Accordingly, the second chamber experiences no metal contamination resulting from the metal gate.

### BACKGROUND

The invention relates to thin film transistor processes, and more particularly, to methods and apparatuses for fabricating thin film transistors.

Bottom-gate type thin film transistors (TFTs) are widely used in thin film transistor liquid crystal displays (TFT-LCDs). As the size of TFT-LCD panels increase, metals having low resistance are required. For example, gate lines employ low resistance metals such as Cu and Cu alloy in order to improve operation of the TFT-LCD. Cu, however, has unstable properties such as poor adhesion with the glass substrate. The poor adhesion causes a film peeling problem. Cu also has a tendency to diffuse into silicon film and must be mixed with other metals such as Cr or Mg, thereby increasing the resistance thereto. Moreover, Cu is vulnerable to deformation due to its weakness. Specifically, in a plasma process for depositing a film, characteristic degradation such as roughness and resistance of Cu are increased by reaction between Cu and the plasma.

U.S. Pat. No. 6,165,917 to Batey et al., the entirety of which is hereby incorporated by reference, discloses a method for passivating Cu. The method uses an ammonia-free silicon nitride layer as a cap layer covering a Cu gate.

U.S. Publication No. 2002/0042167 to Chae, the entirety of which is hereby incorporated by reference, discloses a method of forming a TFT. A metal layer such as Ta, Cr, Ti or W is deposited on a substrate. A Cu gate is defined on the metal layer. Thermal oxidation is then performed to diffuse the material of the metal layer along the surface of the Cu gate. Thus, the Cu gate is surrounded by a metallic oxide generated by the thermal treatment. The metallic oxide is tantalum oxide, chrome oxide, titanium oxide or tungsten oxide.

U.S. Pat. No. 6,562,668 to Jang et al., the entirety of which is hereby incorporated by reference, discloses a method of forming a TFT. The method uses an aluminum oxide or aluminum nitride layer as an adhesion layer between a Cu gate and a glass substrate and a cap layer covering the Cu gate.

While conventional technology prevents Cu diffusion out of the Cu gate, there is no solution to Cu contamination of the deposition tool during the TFT fabrication.

### SUMMARY

Embodiments of the invention provide a method of forming a thin film transistor. A substrate comprising a gate formed thereon is provided. The substrate is placed in a first reaction chamber. A passivation layer is deposited on the substrate in the first reaction chamber. The substrate is placed in a second reaction chamber. A gate insulating layer and a semiconductor layer are deposited on the passivation layer in the second reaction chamber.

Embodiments of the invention provide another method of forming a thin film transistor. A substrate comprising a gate formed thereon is provided. The substrate is placed in a first reaction chamber. A plasma treatment is performed on a surface of the gate in the first reaction chamber. The substrate is placed in a second reaction chamber. A gate insulating layer and a semiconductor layer are deposited overlying the substrate in the second reaction chamber.

Embodiments of the invention also provide an apparatus for fabricating a thin film transistor, comprising a first reaction chamber for forming a passivation layer overlying a substrate; a second reaction chamber for forming a gate insulating layer and a semiconductor layer overlying the substrate; and a means for transporting the substrate from the first reaction chamber to the second reaction chamber.

Embodiments of the invention provide still another apparatus for fabricating a thin film transistor, comprising a first reaction chamber for performing a surface treatment on a substrate comprising a metal gate, wherein the surface treatment passivates a surface of the metal gate; a second reaction chamber for forming a gate insulating layer and a semiconductor layer overlying the substrate; and a means for transporting the substrate from the first reaction chamber to the second reaction chamber.

A substrate comprising a metal gate formed thereon is brought into the first chamber to form a passivation layer on the metal gate or passivate the surface of the metal gate. The substrate is then brought into the second chamber to form a gate insulating layer and a semiconductor layer overlying the substrate. The second chamber thus experiences no metal contamination resulting from the metal gate.

### DESCRIPTION OF THE DRAWINGS

The invention will become more fully understood from the detailed description given in the following and the accompanying drawings, given by way of illustration only and thus not intended to be limitative, and wherein:

FIG. 1 is a flowchart illustrating embodiments of a manufacturing process for fabricating embodiments of a thin film transistor;

FIGS. 2A-2F are sectional views of a first embodiment of a manufacturing process for fabricating an embodiment of a thin film transistor;

FIGS. 3A-3F are sectional views of a second embodiment of a manufacturing process for fabricating an embodiment of a thin film transistor; and

FIG. 4 is an illustration of cluster tools (400 and 500) that can be used in embodiments of the manufacturing process.

### DETAILED DESCRIPTION

### First Embodiment

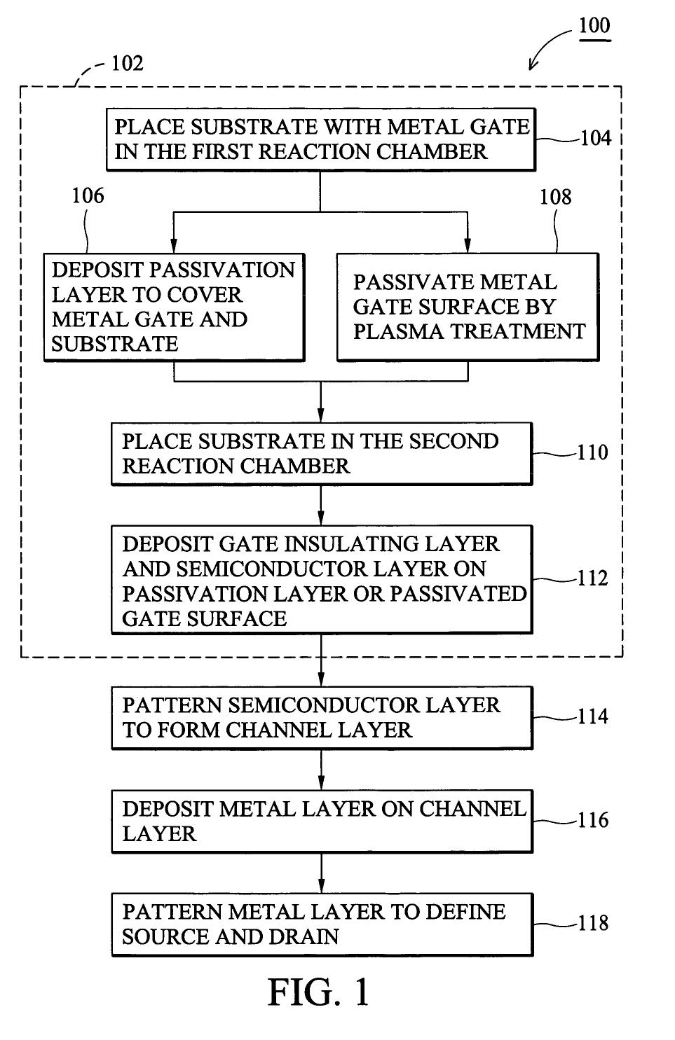

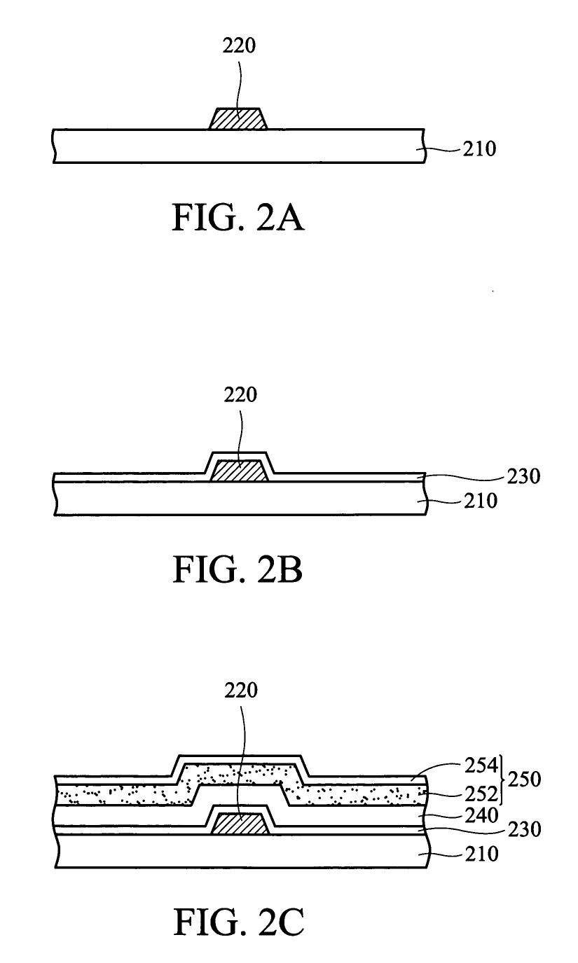

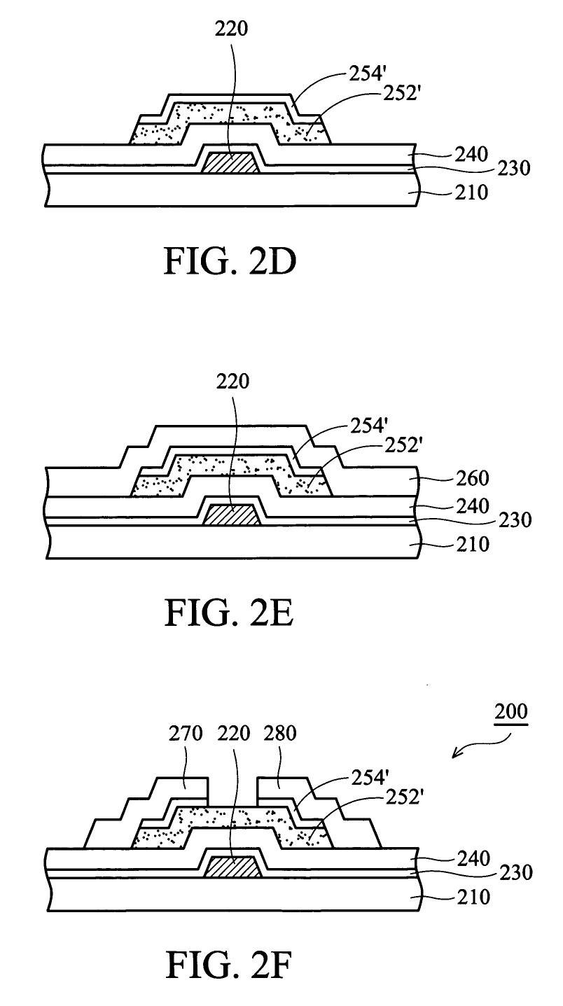

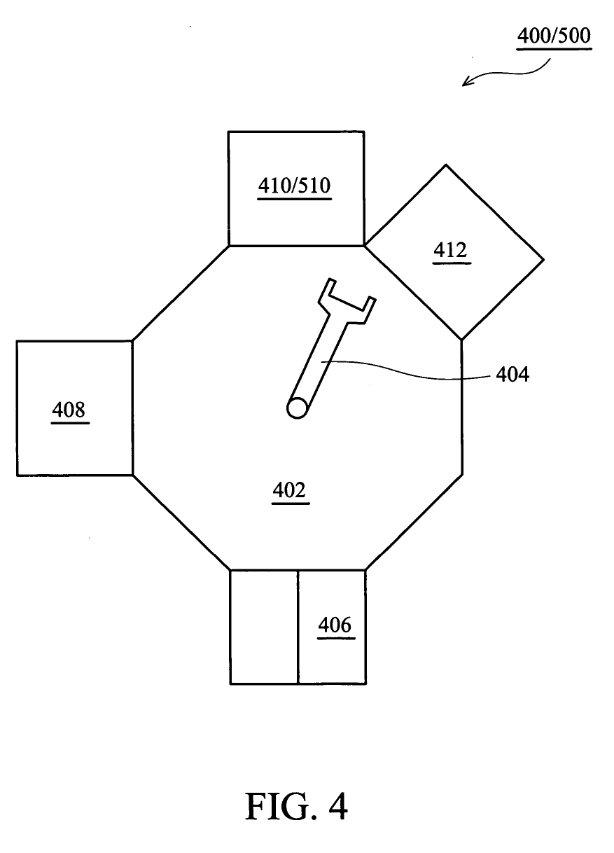

Methods and apparatuses for fabricating thin film transistors are provided. The first embodiment of a method of fabricating an embodiment of a thin film transistor is illustrated in part of the flowchart 100 of FIG. 1. FIGS. 2A-2F are sectional views showing the first embodiment of a manufacturing process. The manufacturing process can be carried out in a cluster tool, such as a double-chamber cluster tool 400 as shown in FIG. 4.

The cluster tool 400 comprises at least one first reaction chamber 410 and at least one second reaction chamber 412. The cluster tool 400 can also comprise a sealable transfer chamber 402 having a substrate handler 404 (e.g. a robot) contained therein, a load lock or a pair of load locks 406, and a preheating chamber 408. The load locks 406 are coupled to the transfer chamber 402 through a sealable door to enable wafers (or substrates) to be brought into and out of the cluster tool 400 by robot 404. Typically, the transfer chamber 402 is held at a reduced pressure and contains an inert ambient, such as N₂. In this way, wafers can be transported from one chamber (e.g. the first reaction chamber 410) to another chamber (e.g. the second reaction chamber 412) and vice versa without exposing the wafer to oxidizing or contaminated ambient. The cluster tool 400 can further comprise a processor/controller (not shown) to control the operation of the invention. For convenience, FIG. 4 shows one preheating chamber 408, one first reaction chamber 410 and one second reaction chamber 412, although there may be numerous chambers 408, 410 and/or 412.

In FIG. 2A, a substrate 210 comprising a gate 220 formed thereon is provided. The substrate 210 can be glass or quartz. The gate 220 can be metal, such as Cu, Al, Mo, Ag, Ag—Pd—Cu, Cr, W, Ti or metal alloy thereof.

The first embodiment of the manufacturing process is then performed. In FIG. 1, a block 102 of the flowchart 100 illustrates the process performed in the cluster tool 400 and can comprise steps 104, 106, 110 and 112. The steps 114, 116 and 118 are performed in tools (not shown) other than the cluster tool 400.

In first step 104, the substrate 210 with the gate 220 is transferred from the load locks 406 to the first reaction chamber 410 by the substrate handler 404. Depending on design, the substrate 210 can be preheated in the preheated chamber 408 before arriving at the first reaction chamber 410. The second step 106 is then performed. Referring to FIG. 2B, a passivation layer 230 covering the substrate 210 and the gate 220 is formed in the first reaction chamber 410. The passivation layer 230 can be a transparent insulating layer comprising silicon oxide, silicon nitride, silicon oxynitride, aluminum oxide, aluminum nitride, vanadium oxide, iridium oxide or ruthenium oxide, formed by CVD (chemical vapor deposition) or PVD (physical vapor deposition) . That is, the first reaction chamber 410 can be a CVD or PVD chamber in the first embodiment. Since the first reaction chamber 410 forms the passivation layer 230 to protect the metal gate 220 and prevent metal diffusion, the first reaction chamber 410 can be referred to as pretreatment chamber 410.

In third step 110, the substrate 210 is transported from the first reaction chamber 410 to the second chamber 412 by the substrate handler 404. The fourth step 112 is then performed. Referring to FIG. 2C, a gate insulating layer 240 and a semiconductor layer 250 are formed on the passivation layer 230. The gate insulating layer 240 can comprise silicon oxide, silicon nitride, silicon oxynitride, tantalum oxide or aluminum oxide formed by CVD. The semiconductor layer 250 comprises a silicon layer 252 and a doped silicon layer 254 formed by CVD. The silicon layer 252 can be amorphous silicon and the doped silicon layer 254 can be silicon doped by P or As. That is, the second reaction chamber 412 can be a CVD chamber. Accordingly, the second reaction chamber 412 experiences no metal contamination from the gate 220, ensuring the quality of the insulating layer 240 and the semiconductor layer 250.

The substrate 210 is then transported from the second reaction chamber 412 to the load locks 406 by the substrate handler 404. Next, the substrate 210 reaches other tools to undergo subsequent thin film transistor processes.

In FIG. 2D, step 114 is performed. The semiconductor layer 250 is patterned to form a channel layer 252′ and an ohmic contact layer 254′ by photolithography.

In FIG. 2E, step 116 is performed. A metal layer 260 covering the channel layer 252′ and the gate insulating layer 240 is formed by, for example, sputtering. The metal layer 260 can be Al, Mo, Cr, W, Ta, Ti, Ni or metal alloy thereof.

In FIG. 2F, step 118 is performed. The metal layer 260 is patterned to form a source 270 and a drain 280 by photolithography. Using the source 270 and the drain 280 as a mask, the exposing ohmic contact layer 254′ is removed by etching. A thin film transistor structure 200 is thus obtained.

### Second Embodiment

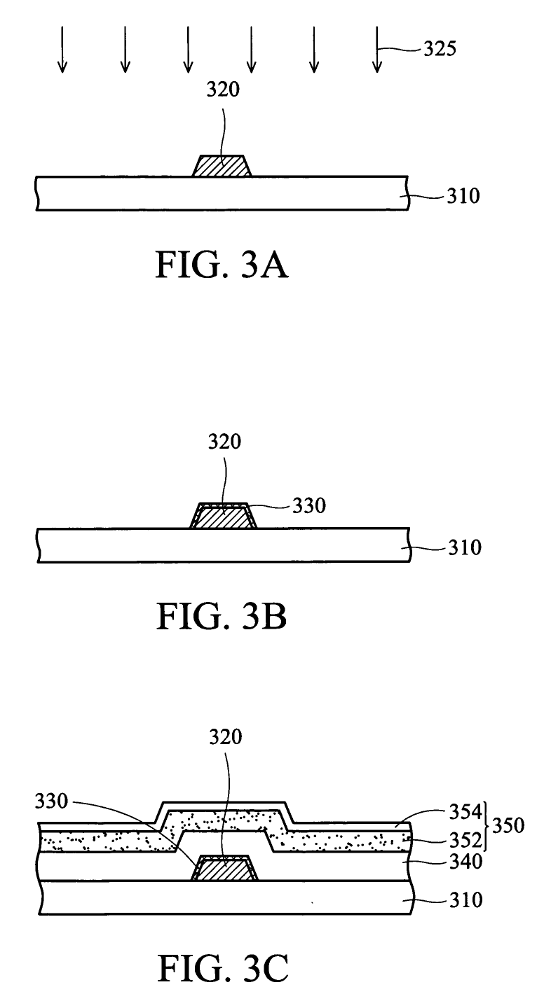

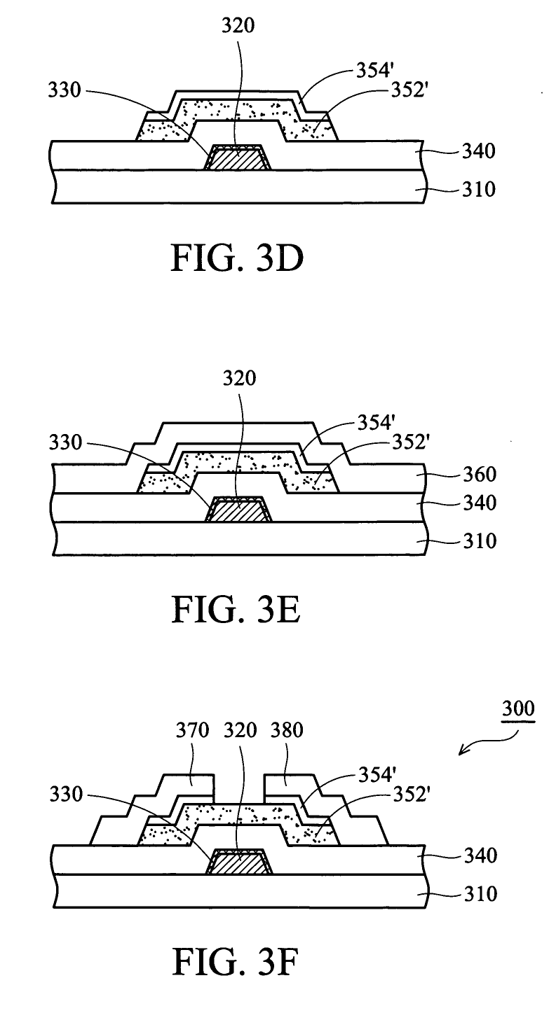

The second embodiment of a method of fabricating an embodiment of a thin film transistor is illustrated in part of the flowchart 100 of FIG. 1. FIGS. 3A-3F are sectional views showing the second embodiment of a manufacturing process. The manufacturing process can be carried out in a cluster tool, such as a double-chamber cluster tool 500 as shown in FIG. 4. Wherever possible, the same reference numbers are used in the drawings and the description of the first and second embodiments to refer to the same or like elements.

The cluster tool 500 comprises at least one first reaction chamber 510 and at least one second reaction chamber 412. The cluster tool 500 can also comprise a sealable transfer chamber 402 having a substrate handler 404 (e.g. a robot) contained therein, a load lock or a pair of load locks 406, and a preheating chamber 408. The load locks 406 are coupled to the transfer chamber 402 through a sealable door to enable wafers (or substrates) to be brought into and out of the cluster tool 500 by robot 404. Typically, the transfer chamber 402 is held at a reduced pressure and contains an inert ambient, such as N₂. In this way, wafers can be transported from one chamber (e.g. the first reaction chamber 510) to another chamber (e.g. the second reaction chamber 412) and vice versa without exposing the wafer to oxidizing or contaminated ambient. The cluster tool 500 can further comprise a processor/controller (not shown) to control the operation of the invention. In order to simplify the illustration, FIG. 4 shows one preheating chamber 408, one first reaction chamber 510 and one second reaction chamber 412, although there may be numerous chambers 408, 510 and/or 412.

In FIG. 3A, a substrate 310 comprising a gate 320 formed thereon is provided. The substrate 310 can be glass or quartz. The gate 320 can be metal, such as Cu, Al, Mo, Ag, Ag—Pd—Cu, Cr, W, Ti or metal alloy thereof.

The second embodiment of the manufacturing process is then performed. In FIG. 1, a block 102 of the flowchart 100 illustrates the process performed in the cluster tool 500 and can comprise steps 104, 108, 110 and 112. The steps 114, 116 and 118 are performed in tools (not shown) other than the cluster tool 500.

In first step 104, the substrate 310 with the gate 320 is transported from the load locks 406 to the first reaction chamber 510 by the substrate handler 404. The second step 108 is then performed. Referring to FIG. 3A, a plasma treatment 325 is performed on the surface of the gate 320 in the first reaction chamber 510. The gate 320 comprising a passivated surface 330 is thus obtained, as shown in FIG. 3B. The plasma treatment 325 can employ plasma of an inert gas. That is, the first reaction chamber 510 is a plasma treatment chamber in the second embodiment. Since the first reaction chamber 510 forms the passivated surface 330 to protect the metal gate 320 and prevent metal diffusion, the first reaction chamber 510 can be referred to as a pretreatment chamber 510.

The third step 110 is performed. The substrate 310 is transported from the first reaction chamber 510 to the second chamber 412 by the substrate handler 404. The fourth step 112 is then performed. Referring to FIG. 3C, a gate insulating layer 340 and a semiconductor layer 350 are formed on the substrate 310 and the passivated surface 330 of the gate 320. The gate insulating layer 340 can comprise silicon oxide, silicon nitride, silicon oxynitride, tantalum oxide or aluminum oxide formed by CVD. The semiconductor layer 350 comprises a silicon layer 352 and a doped silicon layer 354 formed by CVD. The silicon layer 352 can be amorphous silicon and the doped silicon layer 354 can be silicon doped by P or As. That is, the second reaction chamber 412 can be a CVD chamber. Accordingly, the second reaction chamber 412 experiences no metal contamination resulting from the gate 320, ensuring the quality of the insulating layer 340 and the semiconductor layer 350.

The substrate 310 is then transported from the second reaction chamber 412 to the load locks 406 by the substrate handler 404. Next, the substrate 310 reaches other tools to undergo subsequent thin film transistor processes.

In FIG. 3D, step 114 is performed. The semiconductor layer 350 is patterned to form a channel layer 352′ and an ohmic contact layer 354′ by photolithography.

In FIG. 3E, step 116 is performed. A metal layer 360 covering the channel layer 352′ and the gate insulating layer 340 is formed by, for example, sputtering. The metal layer 360 can be Al, Mo, Cr, W, Ta, Ti, Ni or metal alloy thereof.

In FIG. 3F, step 118 is performed. The metal layer 360 is patterned to form a source 370 and a drain 380 by photolithography. Using the source 370 and the drain 380 as a mask, the exposed ohmic contact layer 354′ is removed by etching. A thin film transistor structure 300 is thus obtained.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a thin film transistor, comprising:
providing a substrate comprising a gate formed thereon;
forming a passivation layer on the substrate in a first reaction chamber; and
forming a gate insulating layer and a semiconductor layer on the passivation layer in a second reaction chamber.

2. The method according to claim 1, further comprising:
patterning the semiconductor layer; and
forming a source and a drain on a portion of the semiconductor layer.

3. The method according to claim 1, wherein forming the passivation layer is to deposit the passivation layer on the substrate.

4. The method according to claim 1, wherein forming the passivation layer is to perform a plasma treatment on a surface of the gate.

5. The method according to claim 1, wherein the substrate is a glass or quartz substrate.

6. The method according to claim 1, wherein the gate comprises Cu, Al, Mo, Ag, Ag—Pd—Cu, Cr, W, Ti or metal alloy thereof.

7. The method according to claim 1, wherein the passivation layer is a transparent insulator comprising silicon oxide, silicon nitride, silicon oxynitride, aluminum oxide, aluminum nitride, vanadium oxide, iridium oxide or ruthenium oxide.

8. The method according to claim 1, wherein the gate insulating layer comprises silicon oxide, silicon nitride, silicon oxynitride, tantalum oxide or aluminum oxide.

9. The method according to claim 1, wherein the semiconductor layer comprises a silicon layer and a doped silicon layer.

10. The method according to claim 1, wherein the first reaction chamber is a CVD or PVD chamber.

11. The method according to claim 1, wherein the second reaction chamber is a CVD chamber.

12. The method according to claim 1, wherein a cluster tool comprises the first and second chambers.

13. An apparatus for fabricating a thin film transistor, comprising:
a first reaction chamber for forming a passivation layer;
a second reaction chamber for forming a gate insulating layer and a semiconductor layer ; and
a transport means for transporting a substrate from the first reaction chamber to the second reaction chamber.

14. The apparatus according to claim 13, wherein the first reaction chamber is a CVD or PVD chamber.

15. The apparatus according to claim 13, wherein the first reaction chamber is a plasma treatment chamber.

16. The apparatus according to claim 13, wherein the first reaction chamber is for performing a surface treatment on a gate of the substrate.

17. The apparatus according to claim 13, wherein the second reaction chamber is a CVD chamber.

18. The apparatus according to claim 13, wherein the transport means is a robot.
